(19) United States
(12) Patent Application Publication
(10) Pub. No.: US 2024/0234229 A1
(43) Pub. Date: Jul. 11, 2024

(54) METHOD FOR MAKING A SEMICONDUCTOR DEVICE USING A DOUBLE SIDE MOLDING TECHNOLOGY

(71) Applicant: STATS ChipPAC Pte. Ltd., Singapore (SG)

(72) Inventors: JiEun KWON, Incheon (KR); KyoWang KOO, Incheon (KR); HyunYoung KIM, Seoul (KR); SooBin YOO, Seoul (KR)

(21) Appl. No.: 18/395,641

(22) Filed: Dec. 25, 2023

(30) Foreign Application Priority Data
Jan. 5, 2023 (CN) 202310014563.5

(51) Int. Cl. H01L 23/31; H01L 23/498

(52) U.S. Cl. CPC H01L 23/3121; H01L 23/315; H01L 23/49811

(57) ABSTRACT

A method for making a semiconductor device using a double side molding technology is provided. The method includes: providing a substrate having a first surface and a second surface opposite to the first surface, wherein the second surface of the substrate is uneven; forming a coating on the second surface of the substrate such that a first surface of the coating, which is facing away from the second surface of the substrate, is even; mounting a first electronic component on the first surface of the substrate; and forming a first encapsulant on the first surface of the substrate to cover the first electronic component.

### TECHNICAL FIELD

The present application relates generally to semiconductor technology, and more particularly, to a method for making a semiconductor device using a double side molding technology.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, integrated passive devices (IPD), RF filters, sensors, heat sinks, or antennas. Recently, SiP uses a Double Side Molding (DSM) technology to further shrink the overall package size. Oftentimes, substrates with cavities or copper (Cu) posts are used in the DSM technology. However, the substrates with cavities or Cu posts are susceptible to damages during a surface mounting process, and thus protection films are generally attached onto the substrates to reduce potential damages such as cracks. However, it is found that significant yield loss still occurs to manufacturing processes using such protection films.

Therefore, a need exists for further improvement of the double side molding process.

### SUMMARY OF THE INVENTION

An objective of the present application is to provide a method for making a semiconductor device with higher reliability.

According to an aspect of the present application, a method for making a semiconductor device using a double side molding technology is provided. The method may include: providing a substrate having a first surface and a second surface opposite to the first surface, wherein the second surface of the substrate is uneven; forming a coating on the second surface of the substrate such that a first surface of the coating, which is facing away from the second surface of the substrate, is even; mounting a first electronic component on the first surface of the substrate; and forming a first encapsulant on the first surface of the substrate to cover the first electronic component.

According to another aspect of the present application, a semiconductor device is provided. The semiconductor device can be made according to the aforementioned method.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a semiconductor device formed using a Double Side Molding (DSM) technology.

FIGS. 2A to 2L are cross-sectional views illustrating various steps of a method for making a semiconductor device according to an embodiment of the present application.

FIGS. 3A to 3K are cross-sectional views illustrating various steps of a method for making a semiconductor device according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

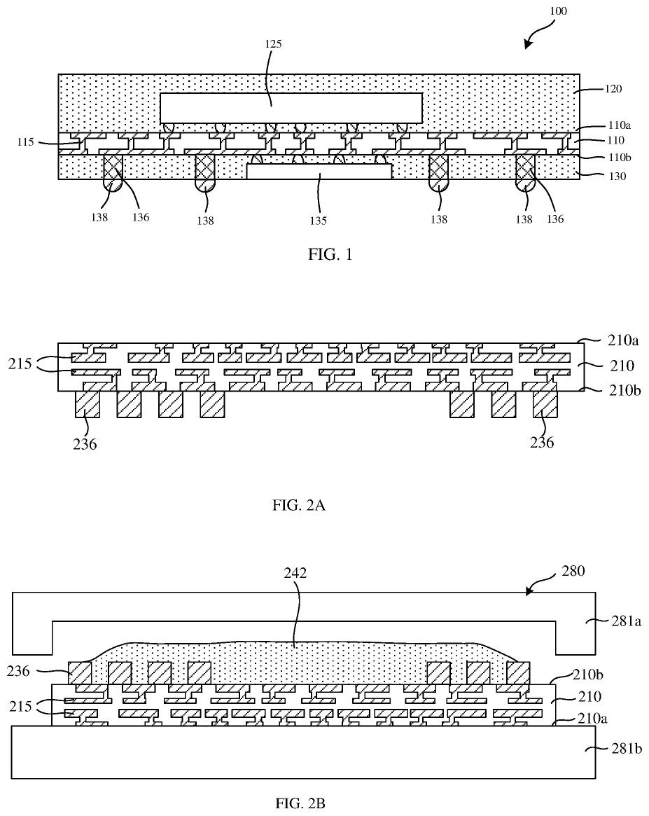

FIG. 1 illustrates a cross-sectional view of a semiconductor device 100 formed using a Double Side Molding (DSM) technology.

As shown in FIG. 1, the semiconductor device 100 includes a substrate 110 having a top surface 110a and a bottom surface 110b. The substrate 110 further includes a redistribution structure (RDS) 115 having one or more dielectric layers and one or more conductive layers between and through the dielectric layers. A plurality of conductive pillars (for example, Cu posts) 136 are formed on the bottom surface 110b of the substrate 110, and are electrically connected to respective conductive patterns of the RDS 115. A top electronic component 125 is mounted on the top surface 110a of the substrate 110, and a bottom electronic component 135 is mounted on the bottom surface 110b. A top encapsulant 120 and a bottom encapsulant 130 are formed on the top surface 110a and the bottom surface 110b of the substrate 110, respectively, so as to protect the top electronic component 125 and the bottom electronic component 135 from external elements and contaminants. For each of the conductive pillars 136, a bump 138 such as a solder ball is further formed onto an exposed surface of the conductive pillar 136 to enable therethrough the connection of internal circuitry of the semiconductor device 100 with an exterior device or system.

The components on the bottom surface 110a and the top surface 110b are usually formed in two steps. In an example, the top electronic component 125 is first mounted on the top surface 110a of the substrate 110, and then the substrate 110 is loaded into a molding apparatus to form the top encapsulant 120. As the substrate 110 may be attached to a chase of the molding apparatus with the conductive pillars 136 in contact with the chase, the conductive pillars 136 are likely to be damaged during the molding process. Moreover, the substrate 110 may be warped because of the high pressure and temperature during the molding process.

In another example, the bottom electronic component 135 and the bottom encapsulant 130 are first formed on the bottom surface 110b of the substrate 110, and then the top electronic component 125 is mounted on the top surface 110a of the substrate 110. Sometimes, a protection film such as an ultraviolet tape may be adhered onto the bottom surface 110a to protect the conductive pillars 136 from being in direct contact with the chase of the molding apparatus, before the molding process of the top encapsulant 120. However, the yield of the devices manufactured in this way may still decrease by about 3% or more due to high strip warpage of the substrate 110 and/or the protection film caused by the molding process.

Similar problems may also occur when a substrate with cavities is used in the DSM technology and covered by similar protection films.

To address at least one of the above problems, a method for making a semiconductor device is provided in an aspect of the present application. In the method, a coating is formed on the bottom surface of the substrate to cover the conductive pillars (or fill the cavities), and then the top electronic component and the top encapsulant can be formed on the top surface of the substrate. The coating can not only protect the conductive pillars, but also prevent the substrate from warpage during the molding process performed on the top surface of the substrate.

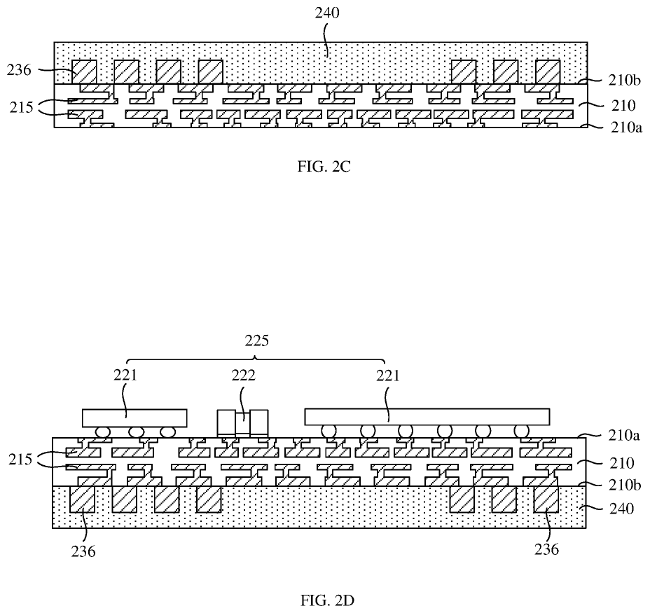

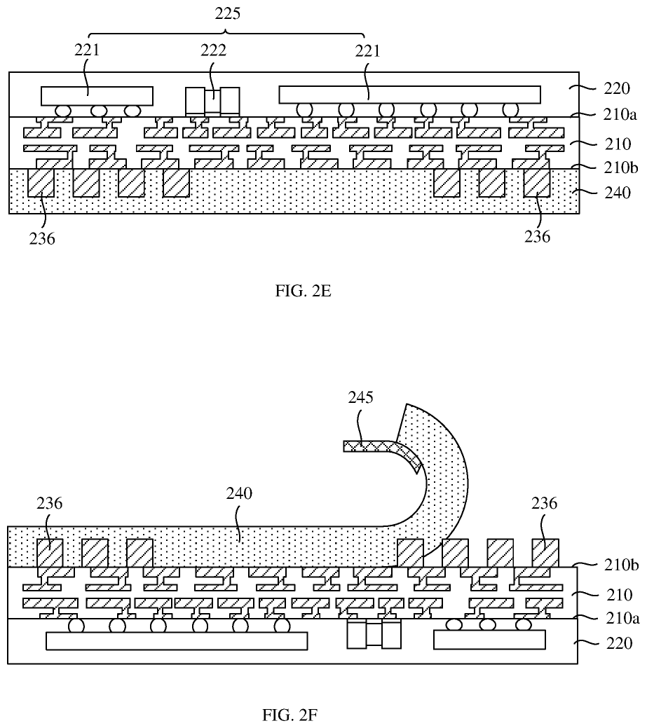

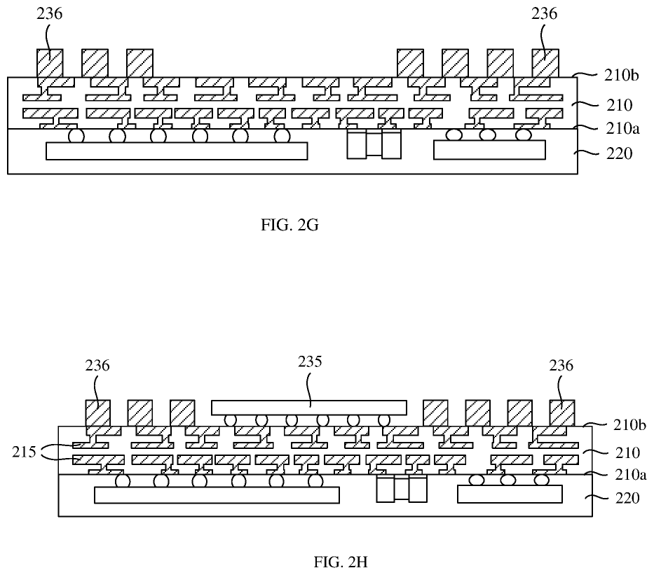

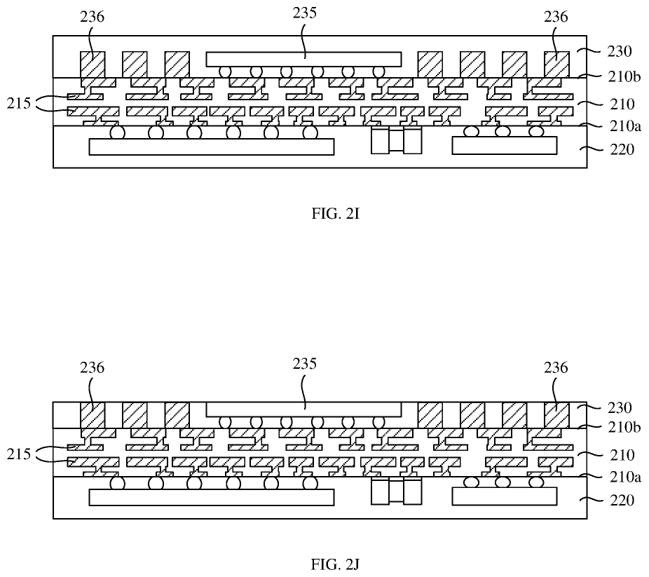

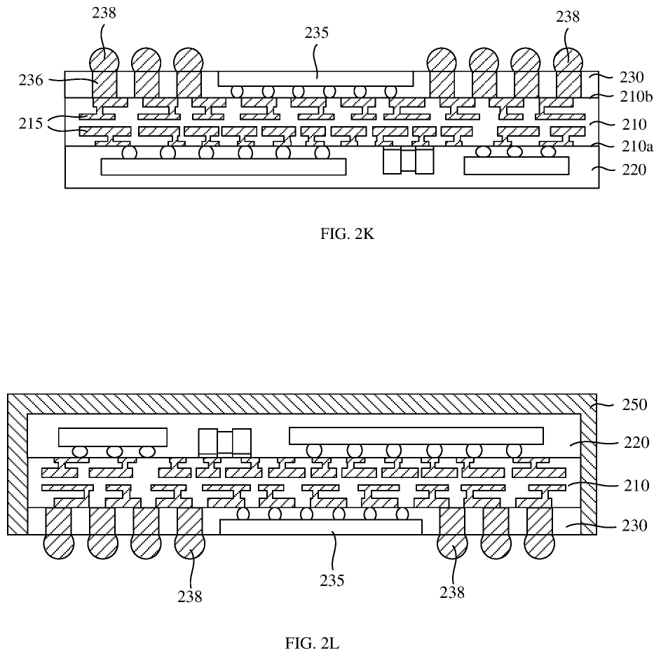

Referring to FIGS. 2A to 2L, cross-sectional views of various steps of a method for making a semiconductor device are illustrated according to an embodiment of the present application. The method can be used to manufacture the semiconductor device shown in FIG. 1, or any other similar devices using the DSM technology. In the following, the method will be described with reference to FIGS. 2A to 2L in more details.

As shown in FIG. 2A, a substrate 210 is provided. The substrate 210 has a first surface 210a and a second surface 210b opposite to the first surface 210a. In some embodiments, the substrate 210 may be a laminate interposer, PCB, wafer-form, strip interposer, leadframe, or any other suitable substrate. The substrate 210 may include one or more insulating or passivation layers, one or more conductive vias formed through the insulating layers, and one or more conductive layers formed over or between the insulating layers. The substrate 210 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The insulating layers may contain one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. The substrate 210 can also be a multi-layer flexible laminate, ceramic, copper clad laminate, glass, or semiconductor wafer including an active surface containing one or more transistors, diodes, and other circuit elements to implement analog circuits or digital circuits.

In the example shown in FIG. 2A, the substrate 210 may include redistribution structures (RDSs) 215 having one or more dielectric layers and one or more conductive layers between and through dielectric layers. The conductive layers may define pads, traces and plugs through which electrical signals or voltages can be distributed horizontally and vertically across the RDS. The RDS 215 may include one or more of Al, Cu, Sn, Ni, Au, Ag, or any other suitable electrically conductive material. It could be appreciated that, the RDS 215 may be implemented in various structures and types, but aspects of the present application are not limited to the above example.

Still referring to FIG. 2A, a plurality of conductive pillars 236 are formed on the second surface 210b of the substrate 210. The conductive pillars 236 may include one or more of Cu, Al, Sn, Ni, Au, Ag, or other suitable electrically conductive material. In an example, each conductive pillar 236 is a copper pillar, but aspects of the present disclosure are not limited thereto. The conductive pillars 236 may be formed on the second surface 210b of the substrate 210, and may be used for electrically connecting the redistribution structures in the substrate 210 with external devices. In an example, the conductive pillars 236 are formed by depositing (e.g., sputtering or plating) one or more layers of conductive material into openings of a mask layer. In other embodiments, conductive pillars 236 are formed using another suitable metal deposition technique or surface mounting technique.

It could be understood that the substrate 210 and the conductive pillars 236 shown in FIG. 2A are only for illustrative purpose and not limiting. In some other embodiments, one or more electronic components (for example, active devices such as semiconductor dice, semiconductor packages, discrete transistors, discrete diodes, etc., or passive devices such as capacitors, inductors, or resistors, etc.) may be attached to the second surface 210b of the substrate 210. The one or more electronic components may have a smaller height than the pillars 236. The one or more electronic components may be attached to the second surface 210bof the substrate 210 before or after the conductive pillars 236 are formed, or may be attached to the second surface 210b of the substrate 210 together with the conductive pillars 236, which is not limited in the present application.

Referring to FIG. 2B and FIG. 2C, a coating 240 is formed on the second surface 210b of the substrate 210. The coating 240 can flatten the substrate 210 so that concentration of stress may not occur to the substrate 210 during subsequent processes.

In some embodiments, as shown in FIG. 2B, a coating apparatus 280 is provided. The coating apparatus 280 may be used for forming a coating over a package. The coating apparatus 280 may include a top chase 281a and a bottom chase 281b. The bottom chase 281b may be used to hold a coating material and a package to be coated. The top chase 281a and the bottom chase 281b may define the geometry of the coating material around the package. Pressure and heat can be applied to the coating material, and the top chase 281a and the bottom chase 281b may compress the coating material to a desired shape and/or geometry around the package. In some cases, the coating apparatus 280 may further include a moving control unit (not shown in FIG. 2B) to move the top chase 281a downward, the bottom chase 281b upward, or both, depending on the requirement of the coating process. It could be understood that the coating apparatus 280 shown in FIG. 2B is only for illustrative purpose and not limiting.

Still referring to FIG. 2B, the substrate 210 is loaded into the coating apparatus 280, and the first surface 210a of the substrate 210 is attached to the bottom chase 281b of the coating apparatus 280. A liquid solution 242 is provided on the second surface 210b of the substrate 210. In an example, the liquid solution 242 may include a silicone elastomer material and an optional additive such as a curing agent or catalyst, and can be used to form a smooth silicone elastomer layer through a compression molding process. For example, the silicone elastomer may include polydimethylsiloxane (PDMS) or any other suitable elastic silicone materials. Afterwards, the top chase 281a and the bottom chase 281b may be moved towards each other to compress the liquid solution 242, and a pressure process may be applied to the liquid solution 242. The top chase 281a and the bottom chase 281b may compress the silicone elastomer to the required shape and/or geometry around the conductive pillars 236 formed on the second surface 210b of the substrate 210, and the silicone elastomer can be solidified under a temperature ranging from 100-170° C. during the compression process. After the silicone elastomer is solidified, the top chase 281a and the bottom chase 281b are separated from each other, and the substrate 210 is removed from the coating apparatus 280.

In another example, the liquid solution 242 may be a solution having a resin material dissolved in an organic solvent, and can be used to form a smooth resin layer through heat treatment. For example, the liquid solution 242 may include epoxy coating compound (EMC), epoxy, urethane and/or any other suitable resin materials which possess adequate mechanical strength, good adhesion to package components, electrical resistance, a low coefficient of thermal expansion, and/or high thermal stability. Afterwards, the top chase 281a and the bottom chase 281b may be moved towards each other to compress the liquid solution 242, and a pressure and heating process may be applied to the liquid solution 242. The heat and pressure within the coating apparatus 280 may be sufficient to cure the liquid solution 242. The top chase 281a and the bottom chase 281b may compress the heated resin material (for example, liquid and/or un-cured resin material) to the required shape and/or geometry around the conductive pillars 236 formed on the second surface 210b of the substrate 210 until the resin material is cured. After the liquid solution 242 is cured and solidified, the top chase 281a and the bottom chase 281b are separated from each other, and the substrate 210 is removed from the coating apparatus 280.

As shown in FIG. 2C, the coating 240 is formed on the second surface 210b of the substrate 210, after the substrate 210 is removed from the coating apparatus. As the solution used in the coating process is liquid or can flow, the coating 240 can fill small gaps among the plurality of the conductive pillars 236, and a top surface of the coating 240 is flattened.

It could be understood that the coating process described with reference to FIG. 2B and FIG. 2C is only for illustrative purpose and not limiting. In other embodiments, the coating may be formed by a spin-coating or other suitable processes.

Referring to FIG. 2D, the substrate 210 is flipped with the first surface 210a oriented upward, and one or more first electronic components 225 may then be mounted on the first surface 210a of the substrate 210, with the substrate 210 supported on a platform or a holder via the coating 240.

In some embodiments, solder paste may be deposited or printed onto top conductive patterns of the redistribution structures 215 at locations where the first electronic component(s) 225 may be surface mounted. The solder paste can be dispensed by jet printing, laser printing, pneumatically, by pin transfer, using a photoresist mask, by stencil-printing, or by another suitable process. Then, the first electronic components 225 may be mounted on the first surface 210a with terminals of the first electronic components 225 in contact with and over the solder paste. The solder paste may be reflowed to mechanically and electrically couple the first electronic components 225 to the top conductive patterns. The first electronic components 225 may include one or more semiconductor dice 221 and discrete devices 222. The first electronic components 225 may be passive or active devices as desired to implement any given electrical functionality within the semiconductor package to be formed. The first electronic components 225 may be active devices such as semiconductor dice, semiconductor packages, discrete transistors, discrete diodes, etc. The first electronic components 225 may also be passive devices such as capacitors, inductors, or resistors.

Referring to FIG. 2E, a first encapsulant 220 is form on the first surface 210a of the substrate 210 to cover the first electronic component 225.

For example, the first encapsulant 220 may be formed on the first surface 210a of the substrate 210 using a compression molding process. In some other embodiments, the first encapsulant 220 may be formed using paste printing, compression molding, transfer molding, liquid encapsulant molding, vacuum lamination, spin coating, or other suitable process. The first encapsulant 220 may be made of polymer composite material, such as epoxy resin with filler, epoxy acrylate with filler, or polymer with proper filler, but the scope of this application is not limited thereto. The first encapsulant 220 may protect the first electronic component 225 from external elements and contaminants. In some examples, the first encapsulant 220 may be planarized, if desired.

Continuing with reference to FIG. 2F and FIG. 2G, the substrate 210 can be flipped again, and then the coating 240 is removed from the second surface 210b of the substrate 210 to expose the plurality of conductive pillars 236. The property of the coating 240 ensures that it can be removed from the substrate 210 but the conductive pillars 236 may not be released off with the removed coating 240.

In the example shown in FIG. 2F, the substrate 210 is flipped with the coating 240 oriented upward. A de-taping tape 245 is attached to the coating 240, and is used to peel the coating 240 from the second surface 210b of the substrate 210. The peeling process can be performed manually or by a de-taping system. However, the present application is not limited thereto. In some other embodiments, a laser ablation process or an etching process may be used to remove the coating 240 from the second surface 210b of the substrate 210.

Afterwards, as shown in FIG. 2H, a second electronic component 235 is mounted on the second surface 210b of the substrate 210. For example, some conductive patterns of the RDS 215 may be exposed after the coating 240 is removed from the second surface 210b of the substrate 210. Then, solder paste may be patterned onto the exposed conductive patterns of the RDS 215, and the second electronic component 235 is surface mounted on the second surface 210b of the substrate 210 through the solder paste. In the example shown in FIG. 2H, the second electronic component 235 is shown as a semiconductor die. In some other embodiments, a plurality of semiconductor dice or one or more discrete devices can be surface mounted on the second surface 210b of the substrate 210 through the solder paste. As can be seen, it is preferred to mount the second electronic component 235 after forming and removing the coating 240, because the coating 240 may be filled between the second electronic component 235 and the substrate 210 if the second electronic component 235 is mounted at an early stage.

Referring to FIG. 2I, a second encapsulant 230 is formed on the second surface 210b of the substrate 210 to cover the plurality of conductive pillars 236 and the second electronic component 235. For example, the second encapsulant 230 may be non-conductive and environmentally protect the second electronic component 235 and the conductive pillars 236 from external elements and contaminants. In some cases, the second encapsulant 230 may be formed using a process similar to the compression molding process forming the first encapsulant 220. In some cases, the second encapsulant 230 may be formed using a paste printing, transfer molding, liquid encapsulant molding, vacuum lamination, spin coating, or other suitable applicator. The second encapsulant 230 and the first encapsulant 220 may be made of the same material, for example, an epoxy-based resin. In some examples, the second encapsulant 230 may be planarized, if desired.

Referring to FIG. 2J, the second encapsulant 230 can be grinded to expose a top surface of each of the plurality of conductive pillars 236. In some embodiments, a grinding operation with grinder, or another suitable chemical or mechanical grinding or etching process, can be used to reduce a thickness of the second encapsulant 230 and expose the conductive pillars 236. The grinding process may result in that a top surface of the second encapsulant 230 is coplanar with top surfaces of the conductive pillars 236 by removing portions of the second encapsulant 230. In the example shown in FIG. 2J, the top surface of the conductive pillar 236 is substantially coplanar with a top surface of the second electronic component 235, and thus the top surface of the second electronic component 235 is also exposed from the second encapsulant 230 after the grinding process. In some other examples, the top surface of the second electronic component 235 may be lower than the top surface of the conductive pillar 236, and the top surface of the second electronic component 235 may still be covered by the second encapsulant 230 after the grinding process.

Referring to FIG. 2K, a bump 238 is formed on the exposed surface of each conductive pillar 236. In some embodiments, an electrically conductive bump material may be deposited on the exposed surface of each conductive pillar 236 using one of or any combination of the following processes: evaporation, electrolytic plating, electroless plating, ball drop, or screen printing process. The conductive bump material may include Al, Sn, Ni, Au, Ag, Pb, Bi, Cu, solder, and combinations thereof, with an optional flux solution. For example, the conductive bump material may be solder paste, and the solder paste is printed onto the exposed surface of each conductive pillar 236. Then, the conductive bump material may be reflowed by heating the material above its melting point to form conductive balls or bumps 238. Each bump 238 may cover the exposed surface of a respective conductive pillar 236. The bumps 238 may extend over the top surface of the second encapsulant 230, and enable electrical connection between the internal circuitry of the semiconductor device with an exterior device or system. In a case that the conductive bump material includes flux solution, a deflux operation may be further performed to clean the flux solution. In some other embodiments, the bumps 238 can also be compression bonded or thermocompression bonded to the respective conductive pillars 236. The hemispherical bump 238 shown in FIG. 2K may represent one type of interconnect structure that can be formed over the conductive pillar 236. In other examples, each of the bumps 238 may be a stud bump, a micro bump, or other electrical interconnects.

At last, referring to FIG. 2L, an electromagnetic interference (EMI) shielding layer 250 is formed, and the EMI shielding layer 250 may at least cover the top and lateral surfaces of the first encapsulant 220. In some embodiments, the EMI shielding layer 250 may be formed from copper, aluminum, iron, or any other suitable material for EMI shielding. In some embodiments, the EMI shielding layer 250 may be formed by spray coating, plating, sputtering, or any other suitable metal deposition process. The EMI shielding layer 250 may be a conformal shield that follows the shapes and/or contours of the first encapsulant 220, the substrate 210, and the second encapsulant 230. Specifically, as shown in FIG. 2L, the EMI shielding layer 250 covers the top and lateral surfaces of the first encapsulant 220, the lateral surface of the substrate 210, and the lateral surface of the second encapsulant 230. However, the bumps 238, the bottom surface of the second encapsulant 230 and the bottom surface of the second electronic component 235 are exposed from the EMI shielding layer 250. The EMI shielding layer 250 can shield EMI or other interferences induced to (or generated by) the electronic components within semiconductor device.

In some embodiments, in order to form multiple semiconductor devices simultaneously, the steps described above can be performed on a strip-based substrate. The strip-base substrate can be singulated into individual semiconductor devices after the bumps are formed on the conductive pillars, and then the EMI shielding layer can be formed on each individual semiconductor device.

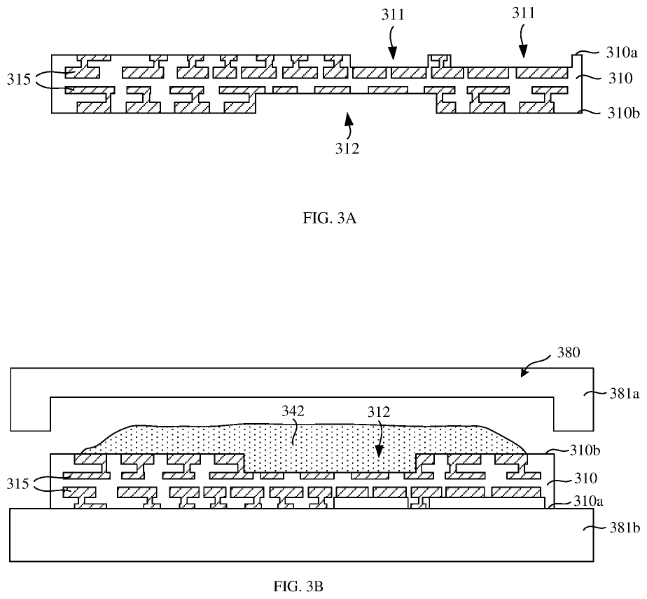

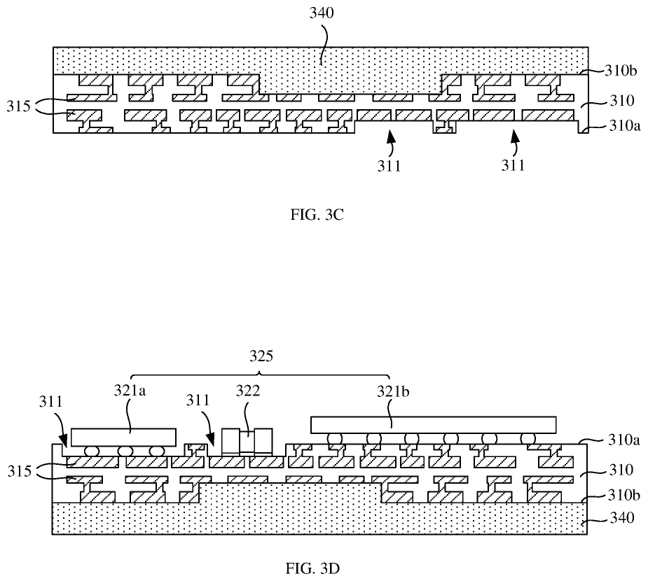

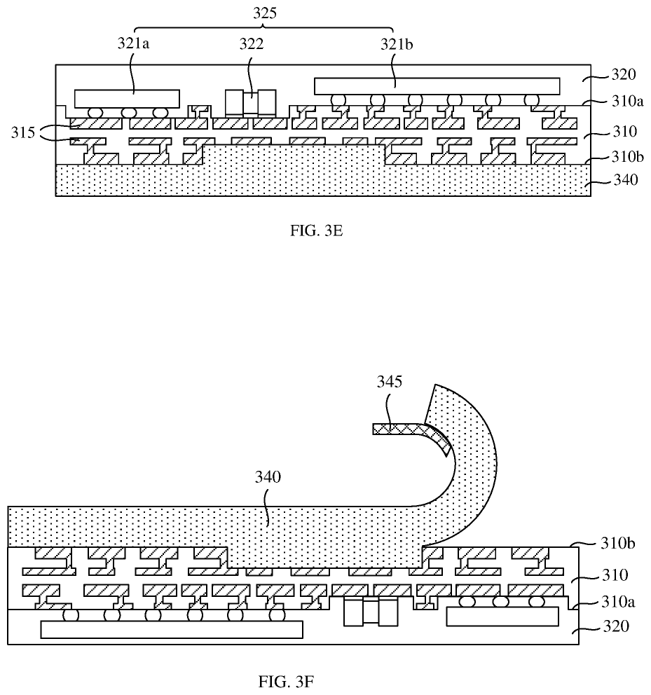

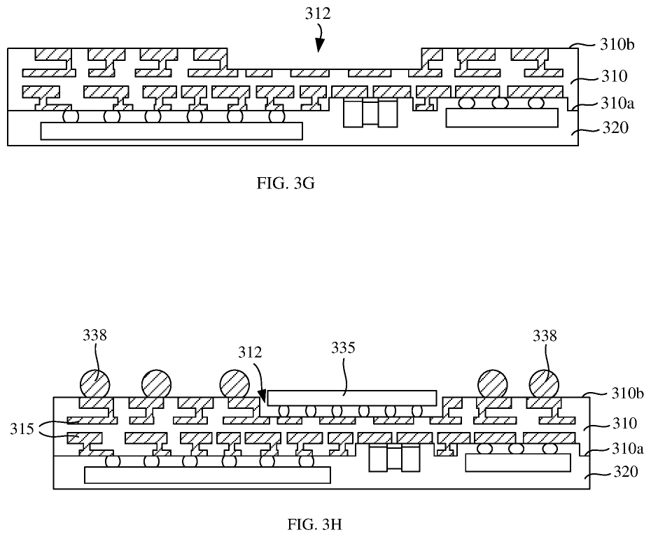

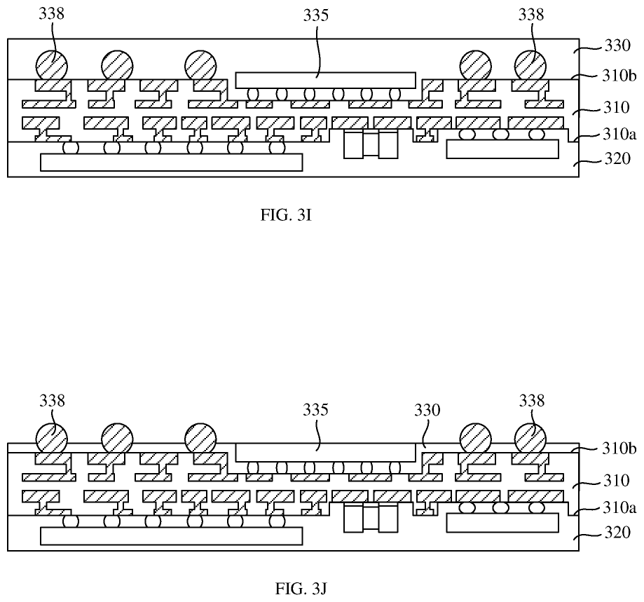

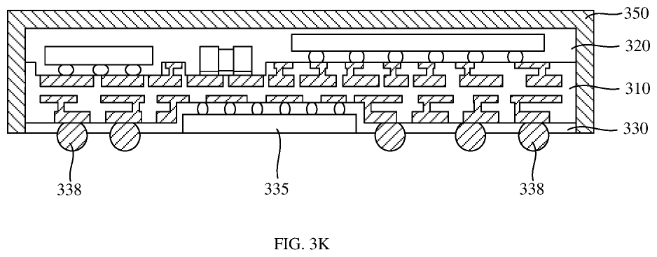

Referring to FIGS. 3A-3K, cross-sectional views of various steps of a method for making a semiconductor device are illustrated according to another embodiment of the present application. Different from the embodiment described with reference to FIGS. 2A-2L, the substrate used in this embodiment may have one or more cavities which similarly undulate a surface of the substrate as the conductive pillars shown in FIGS. 2A-2L.

Referring to FIG. 3A, a substrate 310 is provided. The substrate 310 has a first surface 310a and a second surface 310b opposite to the first surface 310a. One or more redistribution structures 315 may be formed in the substrate 310. The substrate 310 and the redistribution structures 315 are similar as the substrate 210 and the redistribution structures 215 shown in FIG. 2A, respectively, and will not be described in detail herein.

Different from the substrate 210 shown in FIG. 2A, at least one first cavity 311 is formed in the first surface 310a of the substrate 310, and at least one second cavity 312 is formed in the second surface 310b of the substrate 310 shown in FIG. 3A. The first cavity 311 and the second cavity 312 can accommodate electronic components to be mounted on the substrate 310, so as to reduce a total thickness of the semiconductor device to be formed. Specifically, each of the first cavity 311 and the second cavity 312 formed in the substrate 310 may have an area approximately the size as, or bigger than an electronic component later mounted in the cavity. The first cavity 311 and/or the second cavity 312 may be formed by laser, drilling, router, skiving, or scoring.

Referring FIG. 3B and FIG. 3C, a coating 340 is formed on the second surface 310b of the substrate 310. For example, the substrate 310 is loaded into the coating apparatus 380 as shown in FIG. 3B. The first surface 310a of the substrate 310 is attached to a bottom chase 381b of the coating apparatus 380, and a liquid solution 342 is provided on the second surface 310b of the substrate 310 and fills the second cavity 312 in the second surface 310b of the substrate 310. Afterwards, the top chase 381a and the bottom chase 381b may be moved to each other to compress the liquid solution 342, and a pressure process may be applied to the liquid solution 342. After the liquid solution 342 is solidified, the top chase 381a and the bottom chase 381b are separated from each other, and the substrate 310 is removed from the coating apparatus 380. Accordingly, as shown in FIG. 3C, a coating 340 with an even top surface is formed on the second surface 310b of the substrate 310. However, the present application is not limited to the example shown in FIG. 3B and 3C. In other embodiments, the coating may be formed by a spin-coating or other suitable processes.

Referring FIG. 3D, one or more first electronic components 325 are mounted on the first surface 310a of the substrate 310. Specifically, the substrate 310 is flipped with the first surface 310a oriented upward, and the first electronic components 325 can be surface mounted on the first surface 310a of the substrate 310 through solder paste. In the example shown in FIG. 3D, the first electronic components 325 may include two semiconductor dice 321a and 321b, and a discrete device 322. As the semiconductor die 321a and the discrete device 322 have a larger thickness than the semiconductor die 321b, the semiconductor die 321a and the discrete device 322 may be mounted in the two first cavities 311 formed in the substrate 310, and the semiconductor die 321b is mounted in an area outside of the two first cavities 311, thereby reducing the total thickness of the semiconductor device to be formed.

Referring to FIG. 3E, a first encapsulant 320 is formed on the first surface 310a of the substrate 310. The first encapsulant 320 may fill gaps left in the first cavities formed in the first surface 310a of the substrate 310, and cover the first electronic component 325. The first encapsulant 320 may be formed using compression molding, transfer molding, liquid encapsulant molding, vacuum lamination, spin coating, paste printing, or another suitable applicator. The first encapsulant 320 may be made of polymer composite material, such as epoxy resin with filler, epoxy acrylate with filler, or polymer with proper filler, but the scope of this application is not limited thereto.

Referring to FIG. 3F and FIG. 3G, the coating 340 is removed from the second surface 310b of the substrate 310 to expose the at least one second cavity 312. As shown in the example shown in FIG. 3F, a de-taping tape 345 is attached to the coating 340, and is used to peel the coating 340 from the second surface 310b of the substrate 310. However, the present application is not limited thereto.

Afterwards, as shown in FIG. 3H, a second electronic component 335 is mounted in the second cavity 312, and a plurality of bumps 338 are formed on the second surface 310b of the substrate 310. Specifically, the second electronic components 335 can be surface mounted in the second cavity 312 through solder paste, and the plurality of bumps 338 are electrically connected to respective conductive patterns of the RDS 315. As the second electronic component 335 is mounted in the second cavity 312, the plurality of bumps 338 may extend from the second surface 310b of the substrate 310 and be higher than a top surface of the second electronic component 335. In this way, the second electronic component 335 may not interfere with mounting the semiconductor device onto another device such as a printed circuit board via the bumps 338.

Referring to FIG. 3I, a second encapsulant 330 is formed on the second surface 310bof the substrate 310. The second encapsulant 330 may fill in the gaps left in the second cavity formed in the second surface 310b of the substrate 310, and cover the second electronic component 335 and the plurality of bumps 338. The second encapsulant 330 may be formed using compression molding, transfer molding, liquid encapsulant molding, vacuum lamination, spin coating, paste printing, or another suitable applicator. The second encapsulant 330 may be made of the same material as the first encapsulant 320, for example, an epoxy-based resin.

Referring to FIG. 3J, a portion of a thickness of the second encapsulant 330 is removed to expose at least a top surface of each bump 338. In some embodiments, the portion of the thickness of the second encapsulant 330 can be removed by a laser ablation process, an etching process, or any other process known in the art so long as the encapsulant material can be reduced. In the example shown in FIG. 3J, the top surface of the second electronic component 335 is also exposed from the second encapsulant 330. However, the present application is not limited thereto. In some other embodiments, some encapsulant material may be left above the second electronic component 335.

Afterwards, referring to FIG. 3K, an EMI shielding layer 350 is formed, and the EMI shielding layer 350 may at least cover the top and lateral surfaces of the first encapsulant 320. The EMI shielding layer 350 may be a conformal shield that follows the shapes and/or contours of the first encapsulant 320, the substrate 310 and the second encapsulant 330. Specifically, as shown in FIG. 3K, the EMI shielding layer 350 covers the top and lateral surfaces of the first encapsulant 320, the lateral surface of the substrate 310, and the lateral surface of the second encapsulant 330. The EMI shielding layer 350 can shield EMI or other interferences induced to (or generated by) the electronic components within semiconductor device.

While the process for making semiconductor devices with uneven surfaces (at least during certain stages of the process) are illustrated in conjunction with FIGS. 2A-2L and FIGS. 3A-3K, it will be appreciated by those skilled in the art that modifications and adaptations to the process may be made without departing from the scope of the present invention.

The discussion herein included numerous illustrative figures that showed various portions of a semiconductive device and a method for manufacturing such semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor device, comprising:
providing a substrate having a first surface and a second surface opposite to the first surface, wherein the second surface of the substrate is uneven;
forming a coating on the second surface of the substrate such that a first surface of the coating, which is facing away from the second surface of the substrate, is even;
mounting a first electronic component on the first surface of the substrate; and
forming a first encapsulant on the first surface of the substrate to cover the first electronic component.

2. The method of claim 1, wherein forming the coating on the second surface of the substrate comprises:
attaching the first surface of the substrate onto a bottom chase of a coating apparatus;
forming a liquid solution on the second surface of the substrate;
moving a top chase of the coating apparatus and the bottom chase towards each other to compress the liquid solution between an even inner surface of the top chase and the uneven second surface of the substrate; and
solidifying the liquid solution to form the coating.

3. The method of claim 2, further comprising:
separating the top chase and the bottom chase from each other; and
removing the substrate from the coating apparatus.

4. The method of claim 1, wherein the uneven second surface of the substrate has a plurality of conductive pillars formed thereon.

5. The method of claim 4, further comprising:
removing the coating from the second surface of the substrate to expose the second surface of the substrate.

6. The method of claim 5, further comprising:
mounting a second electronic component on the second surface of the substrate;
forming a second encapsulant on the second surface of the substrate to cover the plurality of conductive pillars and the second electronic component; and
grinding the second encapsulant to expose a top surface of each of the plurality of conductive pillars.

7. The method of claim 6, further comprising:
forming a bump on the top surface of each of the plurality of conductive pillars.

8. The method of claim 1, wherein at least one first cavity is formed in the first surface of the substrate, and the first electronic component is mounted in the at least one first cavity.

9. The method of claim 1, wherein the uneven second surface of the substrate has at least one second cavity formed therein.

10. The method of claim 9, further comprising:
removing the coating from the second surface of the substrate to expose the at least one second cavity.

11. The method of claim 10, further comprising:
mounting a second electronic component in the at least one second cavity;
forming a plurality of bumps on the second surface of the substrate; and
forming a second encapsulant on the second surface of the substrate to cover the second electronic component and the plurality of bumps.

12. The method of claim 11, further comprising:
removing a portion of a thickness of the second encapsulant to expose at least a top surface of each of the plurality of bumps.

13. The method of claim 1, further comprising:
forming an electromagnetic interference (EMI) shielding layer to cover at least the first encapsulant.

14. A semiconductor device, wherein the semiconductor device is made using the method of claim 1.
